(19) United States
(12) Patent Application Publication
(10) Pub. No.: US 2023/0283241 A1
(43) Pub. Date: Sep. 7, 2023

(54) CALCULATION DEVICE, CALCULATION METHOD AND NON-TRANSITORY COMPUTER-READABLE MEDIUM

(71) Applicant: Sumitomo Electric Industries, Ltd., Osaka (JP)

(72) Inventor: Hiroshi YAMAMOTO, Osaka-shi (JP)

(73) Assignee: Sumitomo Electric Industries, Ltd., Osaka (JP)

(21) Appl. No.: 18/117,036

(22) Filed: Mar. 3, 2023

(30) Foreign Application Priority Data
Mar. 7, 2022 (JP) 2022-034400

(51) Int. Cl. H03F 1/08

(52) U.S. Cl. CPC H03F 1/083

(57) ABSTRACT

A calculation device includes a memory and a processor coupled to the memory. The processor is configured to; in an amplifier circuit including an input terminal to which a radio frequency signal is input, a transistor configured to amplify the input radio frequency signal, an output terminal from which the amplified radio frequency signal is output, and a matching circuit connected between the transistor and the output terminal, calculate a radio frequency characteristic of the amplifier circuit, if the calculated radio frequency characteristic of the amplifier circuit is a desired characteristic, calculate, at least one value of a current value and a voltage value at a predetermined portion within the equivalent circuit, and calculate, the deterioration degree of the electric characteristic of the transistor.

### CROSS REFERENCE TO RELATED APPLICATIONS

This application claims priority based on Japanese Patent Application No. 2022-034400 filed on Mar. 7, 2022, and the entire contents of the Japanese patent application are incorporated herein by reference.

### TECHNICAL FIELD

The present disclosure relates to a calculation device, a calculation method, and a non-transitory computer-readable medium, for example, to a calculation device, a calculation method, and a non-transitory computer-readable medium for calculating a deterioration degree of an electrical characteristic of an amplifier circuit.

### BACKGROUND

A radio frequency power amplifier circuit is used in a base station for mobile communication. For example, a transistor such as a gallium nitride high electron mobility transistor (GaN HEMT) is used for the amplifier circuit. A plurality of modes are known as deterioration modes in a deterioration test of an electrical characteristic of a GaN HEMT (for example, Non-PTL 1).

[Non-PTL 1] IEEE TRANSACTIONS DEVICE AND MATERIALS RELIABIILITY, Vol. 15, No. 4, pp. 486 to 494 (2015)

### SUMMARY

According to one aspect of the present disclosure, a calculation device includes a memory; and a processor coupled to the memory. The processor is configured to: in an amplifier circuit including an input terminal to which a radio frequency signal is input, a transistor configured to amplify the input radio frequency signal, an output terminal from which the amplified radio frequency signal is output, and a matching circuit connected between the transistor and the output terminal, calculate, based on an element value of the matching circuit and using an equivalent circuit of the transistor, a radio frequency characteristic of the amplifier circuit, if the calculated radio frequency characteristic of the amplifier circuit is a desired characteristic, calculate, based on the element value and using the equivalent circuit, at least one value of a current value and a voltage value at a predetermined portion within the equivalent circuit, and calculate, based on the at least one value and using data in which the at least one value and a deterioration degree of an electric characteristic of the transistor are associated with each other, the deterioration degree of the electric characteristic of the transistor.

According to another aspect of the present disclosure, a calculation method causes a computer to execute a process. The process includes, in an amplifier circuit including an input terminal to which a radio frequency signal is input, a transistor configured to amplify the input radio frequency signal, an output terminal from which the amplified radio frequency signal is output, and a matching circuit connected between the transistor and the output terminal, calculating, based on an element value of the matching circuit and using an equivalent circuit of the transistor, a radio frequency characteristic of the amplifier circuit, if the calculated radio frequency characteristic of the amplifier circuit is a desired characteristic, calculating, based on the element value and using the equivalent circuit, at least one value of a current value and a voltage value at a predetermined portion within the equivalent circuit, and calculating, based on the at least one value and using data in which the at least one value and a deterioration degree of an electric characteristic of the transistor are associated with each other, the deterioration degree of the electric characteristic of the transistor.

According to the other aspect of the present disclosure, a non-transitory computer-readable recording medium storing a program causes a computer to execute a process. The process includes, in an amplifier circuit including an input terminal to which a radio frequency signal is input, a transistor configured to amplify the input radio frequency signal, an output terminal from which the amplified radio frequency signal is output, and a matching circuit connected between the transistor and the output terminal, calculating, based on an element value of the matching circuit and using an equivalent circuit of the transistor, a radio frequency characteristic of the amplifier circuit; if the calculated radio frequency characteristic of the amplifier circuit is a desired characteristic, calculating, based on the element value and using the equivalent circuit, at least one value of a current value and a voltage value at a predetermined portion within the equivalent circuit; and calculating, based on the at least one value and using data in which the at least one value and a deterioration degree of an electric characteristic of the transistor are associated with each other, the deterioration degree of the electric characteristic of the transistor.

The present disclosure can be realized as a semiconductor integrated circuit that realizes a part or all of the calculation device, or can be realized as a calculation system including the calculation device.

### BRIEF DESCRIPTION OF DRAWINGS

FIG. 1 is a circuit diagram of an amplifier circuit in a first embodiment.

FIG. 2 is a circuit diagram illustrating an equivalent circuit of a large signal model of a FET in the first embodiment.

FIG. 3 is a block diagram of a computer in the first embodiment.

FIG. 4 is a flowchart illustrating a method of designing an amplifier circuit in the first embodiment.

FIG. 5A is a diagram illustrating output power Pout, Gain and PAE with respect to input power Pin.

FIG. 5B is a diagram illustrating output power Pout, Gain and PAE with respect to input power Pin.

FIG. 6 is a diagram illustrating a load line in a large signal model.

FIG. 7 is a schematic diagram illustrating drain current Ids - drain voltage Vds characteristics and deterioration modes.

FIG. 8 is a schematic diagram illustrating drain current Ids - drain voltage Vds characteristics and the load line.

FIG. 9 is a diagram illustrating parameters to time in mode A.

FIG. 10 is a diagram illustrating parameters to time in mode B.

FIG. 11 is a diagram illustrating parameters to time in mode C.

FIG. 12 is an Arrhenius plot illustrating temperature to MTTF in mode A.

FIG. 13 is an Arrhenius plot illustrating temperature to MTTF in mode B.

FIG. 14 is an Arrhenius plot illustrating temperature to MTTF in mode C.

FIG. 15 is a diagram illustrating data stored in a memory of a computer.

FIG. 16 is a flowchart illustrating an example of steps S16 and S18.

FIG. 17 is an Arrhenius plot illustrating temperature to MTTF in modes A to D.

FIG. 18 is an Arrhenius plot illustrating temperature to MTTF in modes A to D.

### DETAILED DESCRIPTION

The amplifier circuit is designed so as to obtain desired radio frequency characteristics by designing the load impedance of the transistor. However, even if the desired radio frequency characteristic is obtained, the deterioration degree of the electrical characteristic does not always fall within a desired range.

It is an object of the present disclosure to provide a calculation device, a calculation method and a non-transitory computer-readable recording medium for calculating a deterioration degree of an electrical characteristic of an amplifier circuit.

### Description of Embodiments of Present Disclosure

First, the contents of embodiments of the present disclosure will be listed and explained.

(1) One embodiment of the present disclosure is a calculation device includes a memory; and a processor coupled to the memory. The processor is configured to: in an amplifier circuit including an input terminal to which a radio frequency signal is input, a transistor configured to amplify the input radio frequency signal, an output terminal from which the amplified radio frequency signal is output, and a matching circuit connected between the transistor and the output terminal, calculate, based on an element value of the matching circuit and using an equivalent circuit of the transistor, a radio frequency characteristic of the amplifier circuit, if the calculated radio frequency characteristic of the amplifier circuit is a desired characteristic, calculate, based on the element value and using the equivalent circuit, at least one value of a current value and a voltage value at a predetermined portion within the equivalent circuit, and calculate, based on the at least one value and using data in which the at least one value and a deterioration degree of an electric characteristic of the transistor are associated with each other, the deterioration degree of the electric characteristic of the transistor.

(2) In [1], the processor may determine whether the calculated deterioration degree is a desired deterioration degree. If it is determined that the calculated deterioration degree is not the desired deterioration degree, the processor may change the element value, calculates, based on the changed element value, the radio frequency characteristic, calculate the at least one value, calculate the deterioration degree, and determine whether the calculated deterioration degree is the desired deterioration degree.

(3) In [1], in calculating of at least one value, the processor may calculate at least one value of a current value at an end of a current source and a voltage value across both ends of the current source within the equivalent circuit as the at least one value.

(4) In [1], in calculating of at least one value, the processor may calculate at least two values of a first value, a second value, and a third value, the first value being at least one of a voltage value and a current value at a first end portion at which a load line has a minimum voltage value in a current-voltage characteristic for a current value at an end of a current source and a voltage value across both ends of the current source within the equivalent circuit, the second value being at least one of a voltage value and a current value at a second end portion at which the load line has a maximum voltage value, the third value being at least one of a direct current component and a direct voltage component in the load line. In calculating of the deterioration degree, the processor may calculate, based on the at least two values, at least two deterioration degrees of the electric characteristic of the transistor, respectively.

(5) In [4], in calculating of the deterioration degree, the processor may calculate, as the deterioration degree of the electric characteristic of the transistor, a worst deterioration degree of the electric characteristic of the at least two deterioration degrees of the electric characteristic.

(6) In [4], in calculating of at least one value, the processor may calculate the first value, the second value, and the third value. In calculating of the deterioration degree, the processor may calculate, based on the first value, the second value, and the third value, three deterioration degrees of the electric characteristic of the transistor, respectively.

(7) In [4], the transistor may be a field effect transistor (FET) having a gate connected to the input terminal and a drain connected to the matching circuit. The current source may be a drain current source within the FET.

(8) In [7], in calculating of at least one value, the processor may calculate a fourth value that is at least one of a current value and a voltage value, the current value being a current value at an end of at least one diode of a diode between the gate and a source and a diode between the gate and the drain within the equivalent circuit, the voltage value being a voltage value across both ends of the at least one diode. In calculating of the deterioration degree the processor may calculate, based on the fourth value, a deterioration degree of an electric characteristic of the FET.

(9) In [1], the processor may acquire an operation temperature of the transistor. In the calculating of the deterioration degree of the electric characteristic of the transistor, the processor may calculate, based on the at least one value and the operation temperature and using data in which the at least one value, the operation temperature, and the deterioration degree of the electric characteristic of the transistor are associated with each other, the deterioration degree of the electric characteristic of the transistor.

(10) A calculation method to be executed by a computer according to the present disclosure includes: in an amplifier circuit including an input terminal to which a radio frequency signal is input, a transistor configured to amplify the input radio frequency signal, an output terminal from which the amplified radio frequency signal is output, and a matching circuit connected between the transistor and the output terminal, calculating, based on an element value of the matching circuit and using an equivalent circuit of the transistor, a radio frequency characteristic of the amplifier circuit; if the calculated radio frequency characteristic of the amplifier circuit is a desired characteristic, calculating, based on the element value and using the equivalent circuit, at least one value of a current value and a voltage value at a predetermined portion within the equivalent circuit; and calculating, based on the at least one value and using data in which the at least one value and a deterioration degree of an electric characteristic of the transistor are associated with each other, the deterioration degree of the electric characteristic of the transistor. Thus, the deterioration degree of the electrical characteristic of the amplifier circuit can be calculated.

(11) A non-transitory computer-readable recording medium storing a program that causes a computer to execute a process, the process comprising: in an amplifier circuit including an input terminal to which a radio frequency signal is input, a transistor configured to amplify the input radio frequency signal, an output terminal from which the amplified radio frequency signal is output, and a matching circuit connected between the transistor and the output terminal, a radio frequency characteristics calculation unit calculating, based on an element value of the matching circuit and using an equivalent circuit of the transistor, a radio frequency characteristic of the amplifier circuit; if the calculated radio frequency characteristic of the amplifier circuit is a desired characteristic, a current value/voltage value calculation unit calculating, based on the element value and using the equivalent circuit, at least one value of a current value and a voltage value at a predetermined portion within the equivalent circuit; and a deterioration degree calculation unit calculating, based on the at least one value and using data in which the at least one value and a deterioration degree of an electric characteristic of the transistor are associated with each other, the deterioration degree of the electric characteristic of the transistor.

### Details of Embodiments of Present Disclosure

Specific examples of a calculation device, a calculation method and a non-transitory computer-readable recording medium according to embodiments of the present disclosure will be described below with reference to the drawings. The present disclosure is not limited to these examples, and is defined by the scope of the claims, and is intended to include all modifications within the meaning and scope equivalent to the scope of the claims.

At least some of the embodiments described below may be arbitrarily combined. The calculation device is configured to include a computer, and each function of the calculation device is performed by a computer program stored in a storage device of the computer being executed by a central processing unit (CPU) of the computer. The computer program can be stored in a storage medium such as a CD-ROM (Compact Disc Read Only Memory).

### First Embodiment

In the following description, a deterioration degree of an electrical characteristic of an amplifier circuit, a transistor, or the like is a degree of the deterioration of the electrical characteristic of the amplifier circuit, the transistor, or the like when the amplifier circuit, the transistor, or the like is continuously used under a certain environment. For example, the lifetime of an amplifier circuit or transistor or the like at a certain operating temperature. By performing a stress test in which stress is applied to a transistor or the like, a deterioration degree of an electrical characteristic of the transistor or the like can be calculated.

### Amplifier Circuit

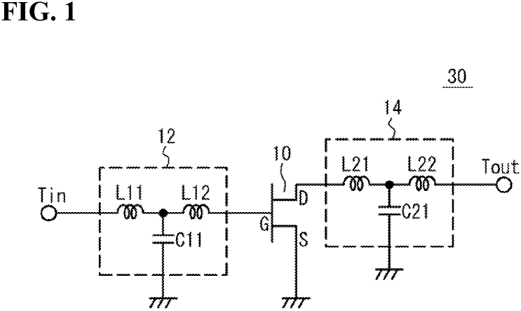

In the first embodiment, an amplifier circuit to be designed will be described using an FET (Field Effect Transistor) as an example of a transistor. FIG. 1 is a circuit diagram of an amplifier circuit according to a first embodiment. As shown in FIG. 1, an amplifier circuit 30 includes a FET 10 and matching circuits 12 and 14. The FET is, for example, a GaN HEMT. A source S of FET 10 is connected to ground and a gate G is connected to an input terminal Tin through matching circuit 12. A drain D of FET 10 is connected to an output terminal Tout through matching circuit 14. Matching circuit 12 is connected between input terminal Tin and FET 10, and includes inductors L11 and L12 connected in series between input terminal Tin and gate G, and a capacitor C11 shunt-connected at a node between inductors L11 and L12. Matching circuit 14 is connected between FET 10 and output terminal Tout, and includes inductors L21 and L22 connected in series between drain D and output terminal Tout, and a capacitor C21 shunt-connected at a node between inductors L21 and L22.

The radio frequency signal input to input terminal Tin is input to gate G of FET 10 through matching circuit 12. FET 10 amplifies the input radio frequency signal. Output terminal Tout outputs the amplified radio frequency signal. Matching circuit 12 matches the input impedance of input terminal Tin to the input impedance of gate G. Matching circuit 14 matches the output impedance of drain D with the output impedance of output terminal Tout. The radio frequency characteristics of amplifier circuit 30 can be set to desired characteristics by designing the values of the element values (the inductances of inductors L11, L12, L21, and L22, and the capacitances of capacitors C11 and C21) of matching circuits 12 and 14. In particular, by adjusting the element value of matching circuit 14, the load impedance of FET 10 can be adjusted and the radio frequency characteristic of amplifier circuit 30 can be adjusted. The circuit configurations of matching circuits 12 and 14 can be appropriately designed. The center frequencies of the band of amplifier circuit 30 are, for example, 0.5 GHz to 10 GHz.

### Equivalent Circuit of Large Signal Model

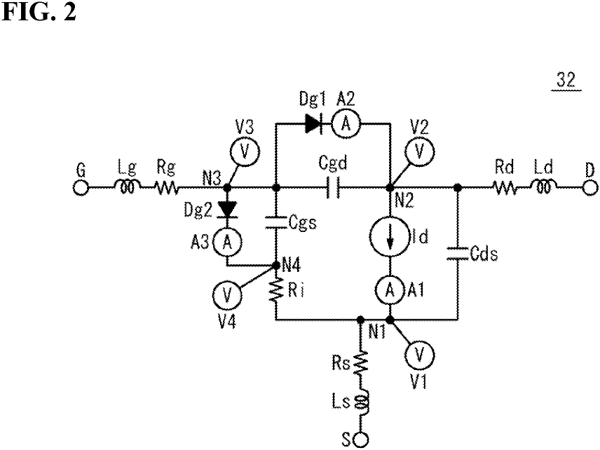

A large signal model is used to design the radio frequency power amplifier circuit. An equivalent circuit of a large signal model used in the first embodiment will be described by taking the FET as an example. FIG. 2 is a circuit diagram illustrating an equivalent circuit of a large signal model of the FET in the first embodiment. As shown in FIG. 2, in an equivalent circuit 32, the drain-source current is represented by a drain current source Id. A node N1 on the source side of drain current source Id is connected to source S through a source resistance Rs and a source inductance Ls. A node N2 on the drain side of drain current source Id is connected to drain D through a drain resistance Rd and a drain inductance Ld. A drain-source capacitance Cds is connected in parallel with drain current source Id between nodes N1 and N2. A node N3 is connected to gate G through a gate resistance Rg and a gate inductance Lg. A gate-drain capacitance Cgd and a diode Dg1 are connected in parallel between nodes N2 and N3. A gate-source capacitance Cgs and a diode Dg2 are connected in parallel between nodes N3 and N4. A channel resistance Ri is connected between nodes N1 and N4. In the case of a GaN HEMT, diode Dg1 corresponds to a Schottky diode between gate G and drain D and diode Dg2 corresponds to a Schottky diode between gate G and source S.

In the first embodiment, ammeters A1 to A3 and voltmeters V1 to V4 are provided in equivalent circuit 32, and a current value and a voltage value of radio frequency at a predetermined portion in equivalent circuit 32 are calculated. Ammeter A1 calculates a current value at an end of drain current source Id. Ammeters A2 and A3 calculate current values at ends of diodes Dg1 and Dg2, respectively. Voltmeters V1 to V4 calculate voltage values of nodes N1 to N4, respectively. The voltage difference between voltmeters V1 and V2 corresponds to the voltage across both ends of drain current source Id. The voltage difference between voltmeters V2 and V3 corresponds to the voltage across both ends of diode Dg1, and the voltage difference between voltmeters V3 and V4 corresponds to the voltage across both ends of diode Dg2.

### Block Diagram of Computer

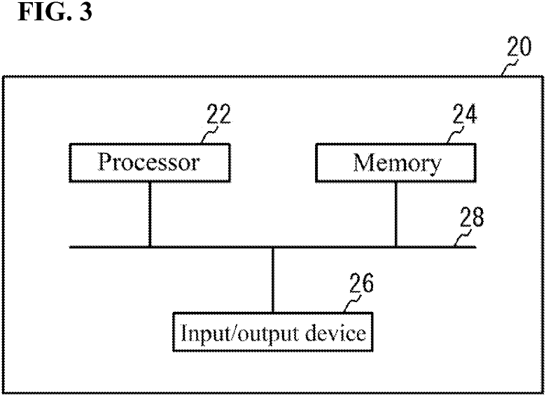

FIG. 3 is a block diagram of a computer according to the first embodiment. A computer 20 functions as a calculation device in cooperation with software. Computer 20 executes the calculation program and performs the calculation method. Computer 20 includes a processor 22, a memory 24, an input/output device 26, and an internal bus 28. Processor 22 is, for example, a CPU, and calculates the deterioration degree of the radio frequency characteristic and the electrical characteristic of amplifier circuit 30 using equivalent circuit 32 of the large signal model. Memory 24 is, for example, a volatile memory or a nonvolatile memory, and stores data and the like. Processor 22 uses the data and the like when calculating the deterioration degree of the radio frequency characteristic and the electrical characteristic. Memory 24 may store a program executed by processor 22. Input/output device 26 inputs data acquired by processor 22 from an external device and outputs data output by processor 22 to the external device. Internal bus 28 connects processor 22, memory 24, and input/output device 26 and transmits data and the like. The calculation program is stored in a storage medium. The storage medium is, for example, a non-transitory tangible medium.

### Flowchart

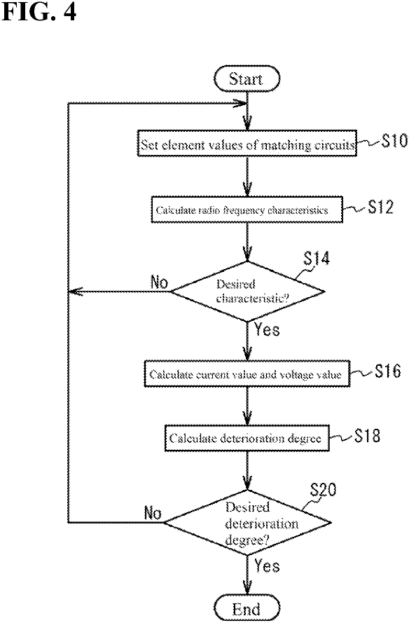

FIG. 4 is a flowchart illustrating a method of designing an amplifier circuit according to the first embodiment. As shown in FIG. 4, the user or computer 20 sets the element values of matching circuits 12 and 14 (step S10). For example, the inductance of inductors L11, L12, L21, and L22 and the capacitance of capacitors C11 and C21 of FIG. 1 are set. Computer 20 calculates the radio frequency characteristics of amplifier circuit 30 based on the element values of matching circuits 12 and 14 set by using equivalent circuit 32 (step S12). For example, computer 20 calculates a output power Pout, a gain, a power added efficiency (PAE), and the like of amplifier circuit 30. The user or computer 20 determines whether or not the calculated radio frequency characteristic is a desired characteristic (step S14). If No, the process returns to step S10. In step S10, the element values of matching circuits 12 and 14 are reset, and steps S12 and S14 are performed. Steps S10 to S14 are repeated until it is determined as Yes in step S14. If it is determined as No in step S14, the user may set the element values of matching circuits 12 and 14 in step S10. In step S10, computer 20 may set the element values of matching circuits 12 and 14. A program using machine learning or the like may be used to change the element value of matching circuit 14 in computer 20.

If Yes in step S14, computer 20 calculates at least one of a current value and a voltage value at a predetermined portion in equivalent circuit 32 based on the element values of matching circuits 12 and 14 set in step S10 (step S16). For example, computer 20 calculates the current value at the end of drain current source Id using ammeter A1 of equivalent circuit 32, and calculates the voltage across both ends of drain current source Id using voltmeters V1 and V2. Further, computer 20 calculates the current value at the end of diode Dg1 by using ammeter A2, calculates the voltage across both ends of diode Dg1 by using voltmeters V2 and V3, calculates the current value at the end of diode Dg2 by using ammeter A3, and calculates the voltage across both ends of diode Dg2 by using voltmeters V3 and V4.

Computer 20 calculates the deterioration degree of the electrical characteristic of the transistor based on the calculated current value and/or voltage value (step S18). For example, memory 24 stores data in which a current value and/or a voltage value at a predetermined portion in equivalent circuit 32 is associated with a deterioration degree of an electrical characteristic of a transistor. Computer 20 calculates the deterioration degree of the electrical characteristic of the transistor based on the data. The deterioration degree of the electrical characteristic is, for example, a lifetime (e.g., mean time to failure (MTTF)) at an operating temperature of the transistor. Computer 20 determines whether the calculated deterioration degree is a desired deterioration degree (step S20). For example, computer 20 determines Yes when the calculated lifetime is equal to or longer than the desired lifetime. If No, the process returns to step S10. In step S10, the element values of matching circuits 12 and 14 are reset, and steps S12 to S20 are performed. Steps S10 to S20 are repeated until it is determined as Yes in Step S20. If it is determined as No in step S20, the user may set the element values of matching circuits 12 and 14 in step S10. In step S10, computer 20 may set the element values of matching circuits 12 and 14. A program using machine learning or the like may be used to change the element value of matching circuit 14 in computer 20. If Yes in step S20, an amplifier circuit having a desired radio frequency characteristic and a desired deterioration degree can be designed.

Processor 22 cooperates with the calculation program to function as a radio frequency characteristic calculation unit, a current value/voltage value calculation unit, a deterioration degree calculation unit, and a deterioration degree determination unit. In step S12, the radio frequency characteristic calculation unit calculates the radio frequency characteristic of amplifier circuit 30. The current value/voltage value calculation unit calculates at least one of a current value and a voltage value at a predetermined portion in equivalent circuit 32 in step S16. The deterioration degree calculation unit calculates a deterioration degree of the electrical characteristic of the transistor in step S18. The deterioration degree determination unit determines whether the calculated deterioration degree of the transistor in step S20 is the desired deterioration degree.

### Example of Radio Frequency Characteristic Calculated in Step S12

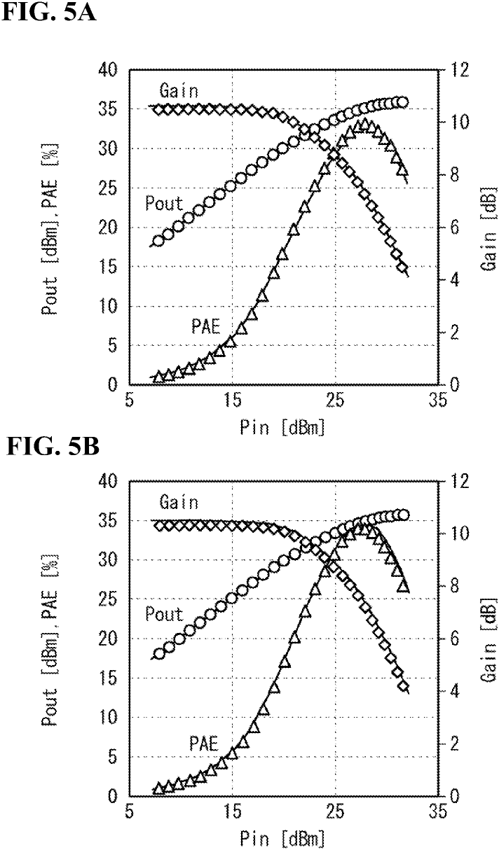

An example of the radio frequency characteristic calculated in step S12 of FIG. 4 will be described. FIG. 5A and FIG. 5B are diagrams illustrating output power Pout, a Gain and the PAE with respect to input power Pin. FIG. 5A shows an example of power matching in which the element values of matching circuits 12 and 14 are set so that the output power Pout becomes maximum. FIG. 5B shows an example of efficiency matching in which the element values of matching circuits 12 and 14 are set so that the PAE becomes maximum. The saturation power (power at which output power Pout is saturated) and the gain in FIG. 5A are larger than those in FIG. 5B. The maximum PAE in FIG. 5B is greater than the maximum PAE in FIG. 5A. As described above, by changing the element values of matching circuits 12 and 14 (particularly, matching circuit 14), the radio frequency characteristics of the transistor are changed. In steps S10 to S14, matching circuits 12 and 14 are designed so that the radio frequency characteristic of amplifier circuit 30 becomes a target desired radio frequency characteristic (for example, power matching or efficient matching).

### Example of Current Value and Voltage Value Calculated in Step S16

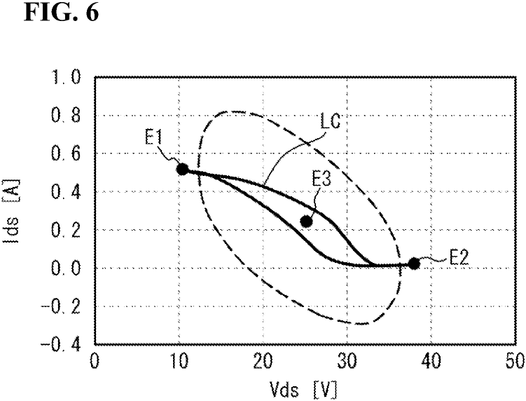

An example of the current value and the voltage value at a predetermined portion of the equivalent circuit calculated in step S16 of FIG. 4 will be described. FIG. 6 is a diagram illustrating a load line in a large signal model. FIG. 6 shows drain current Ids with respect to drain voltage Vds (Ids-Vds characteristic). A load line indicates a curve on Ids-Vds when a radio frequency signal having a large amplitude is input as an input signal. FIG. 6 shows an example of the load line when the radio-frequency signal is 14 GHz, matching is power matching, and input power is power backed off by 3 dB from the input signal which is saturation power. The dashed line is the load line between drain D and source S, and the solid line is the load line at the end of drain current source Id (between nodes N1 and N2 in FIG. 2). As shown in FIG. 6, the load line of the dashed line has a large hysteresis. This is due to the influence of a reactance component such as Cds. Hysteresis in the load line of the solid line is small. This is because although a small hysteresis occurs due to the nonlinearity of Cgs, it is not affected by a large reactance component such as Cds. The load line affecting the degradation of the electrical characteristics is a load line LC of the solid line at the end of drain current source Id. Among the end portions of load line LC, the end portion having a minimum drain voltage Vds is referred to as E1, and the end portion having a maximum drain voltage Vds is referred to as E2. The direct components (a direct component of the current and a direct component of the voltage) in load line LC are E3. The direct current component corresponds to a direct component when the current at the end of drain current source Id with respect to time is Fourier-transformed. The direct voltage component corresponds to a direct component when the voltage across both ends of drain current source Id with respect to time is Fourier-transformed.

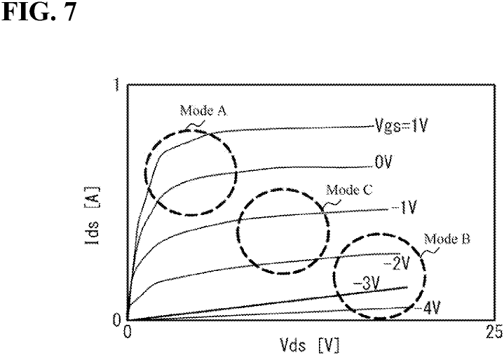

FIG. 7 is a schematic diagram illustrating drain current Ids - drain voltage Vds characteristics and deterioration mode. The thin curve in FIG. 7 shows the direct Ids-Vds characteristic when a gate voltage Vgs is changed. Vgs is changed from 1 V to -4 V in 1 V steps. Like the Non-PTL 1, there are a plurality of deterioration modes of the transistor, and the deterioration mode most affected by the values of Vds and Ids is different. For example, in the case of a GaN HEMT, in a region where Vds is low and Ids is high, the deterioration mode of the transistor is a mode A. Mode A is a mode in which the transistor deteriorates due to temperature, for example. For example, in a region where Vds is high and Ids is low, the deterioration mode of the transistor is a mode B. Mode B is a mode in which the transistor deteriorates due to breakdown between the gate and the drain caused by, for example, a high electric field between the gate and the drain even when no current flows. For example, in a region where Vds and Ids are medium, the deterioration mode of the transistor is a mode C. Mode C is a mode in which, for example, electrons flowing through a channel become hot electrons and are trapped by a trap in a semiconductor layer or an insulating layer between a gate and a drain, so that the transistor deteriorates. Even when the transistor is other than the GaN HEMT, the transistor deteriorates due to the deterioration mode that varies depending on the current value and the voltage value at the end of the current source.

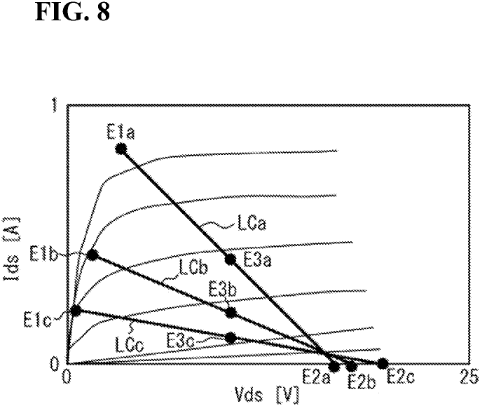

FIG. 8 is a schematic diagram illustrating drain current Ids - drain voltage Vds characteristics and a load line. As shown in FIG. 8, load lines LCa to LCc are shown. Load lines LCa to LCc can be changed by changing the element values of matching circuits 12 and 14. Ids-Vds at the first end portion, the second end portion, and the direct components of load line LCa are denoted by E1a, E2a, and E3a, respectively. Ids-Vds at the first end portion, the second end portion, and the direct components of load line LCb are denoted by E1b, E2b, and E3b, respectively. Ids-Vds at the first end portion, the second end portion, and the direct components of load line LCc are denoted by E1c, E2c, and E3c, respectively.

When FIG. 7 is compared with FIG. 8, at first end portions E1a to E1c, the deterioration mode of the transistor is mainly mode A. At second end portions E2a to E2c, the deterioration mode of the transistor is mainly mode B. At direct components E3a to E3c, the deterioration mode is mainly mode C. Therefore, the deterioration degree in mode A can be calculated using the current values and the voltage values of first end portions E1a to E1c. The deterioration degree in mode B can be calculated using the current values and the voltages value of second end portions E2a to E2c. The deterioration degree in mode C can be calculated using the current values and the voltage values of direct components E3a to E3c. Depending on the deterioration mode, either the current value or the voltage value may contribute to the deterioration of the transistor, or both the current value and the voltage value may contribute to the deterioration of the transistor. Therefore, in step S16 of FIG. 4, for example, the current value and/or the voltage value of at least one of first end portion E1, second end portion E2, and direct component E3 is calculated.

### Data Generation Method Used in Step S18

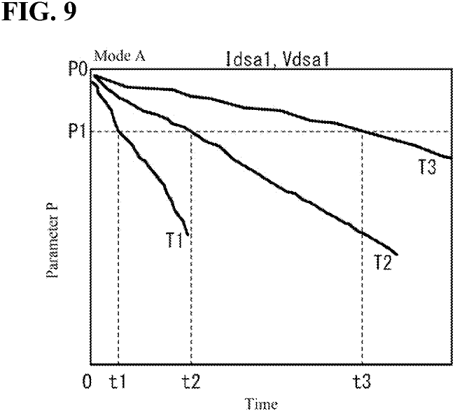

A method of calculating the deterioration degree for each mode will be described in advance. FIGS. 9 to 11 are diagrams illustrating parameters with respect to time in modes A to C, respectively. In FIGS. 9 to 11, the horizontal axis represents the stress time during which a predetermined drain current Ids and drain voltage Vds are applied. Note that in order to change Ids at the same Vds, Vgs is changed. The vertical axis represents a parameter P that deteriorates when a predetermined drain current Ids and drain voltage Vds are applied. Parameter P is, for example, at least one of a threshold voltage Vth, a mutual conductance gm, and drain current Ids. The operating temperature of the transistor is set to any one of T1 to T3, and drain current Ids and drain voltage Vds are set to predetermined values. Thus, temperature stress and current and voltage stress are applied to the transistor. T1 to T3 are T1, T2, and T3 in descending order of temperature. When parameter P is measured, the temperature is set to room temperature. Parameter P changes with the stress time. Parameter P at time 0 (i.e., before a predetermined drain current Ids and drain voltage Vds are applied) is defined as P0, and parameter P at which parameter P is changed by a predetermined amount from P0 is defined as P1. When parameter P reaches P1, it is determined that the transistor is deteriorated. Depending on temperatures T1 to T3, the time at which parameter P becomes P1 varies.

As shown in FIG. 9, in mode A, the stress test is performed at a drain current Idsa1 and a drain voltage Vdsa1 with drain current Ids and drain voltage Vds corresponding to first end portion E1. The time when parameter P becomes P1 in the temperature range of T1 to T3 is t1 to t3. Stress testing is performed on multiple samples at the same temperature. In the plurality of samples, the mean value of time t1 is the MTTF of temperature T1, the mean value of time t2 is the MTTF of temperature T2, and the mean value of time t3 is the MTTF of temperature T3.

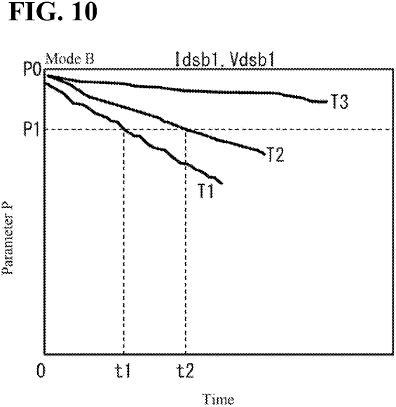

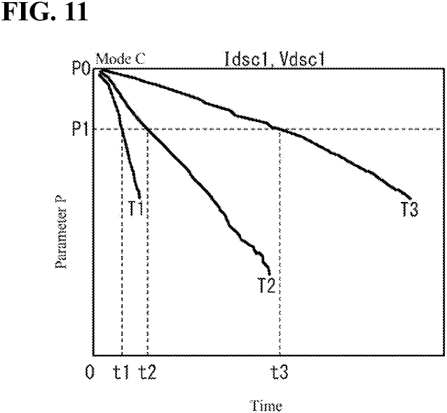

As shown in FIG. 10, in mode B, the stress test is performed at a drain current Idsb1 and a drain voltage Vdsb1 with drain current Ids and drain voltage Vds corresponding to second end portion E2. Using a plurality of samples, the MTTF is calculated at temperatures T1 to T3. As shown in FIG. 11, in mode C, the stress test is performed at a drain current Idsc1 and a drain voltage Vdsc1 with drain current Ids and drain voltage Vds corresponding to direct component E3 . The MTTF is calculated for each of temperatures T1 to T3 using a plurality of samples.

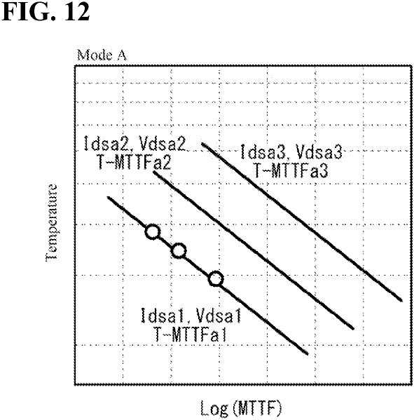

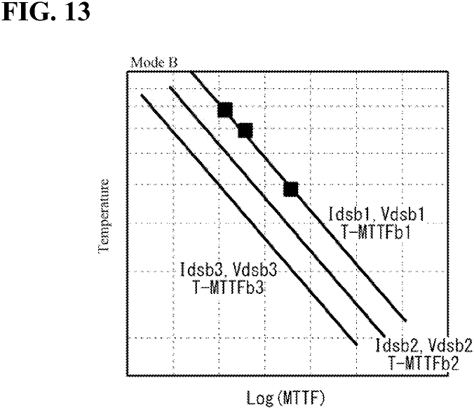

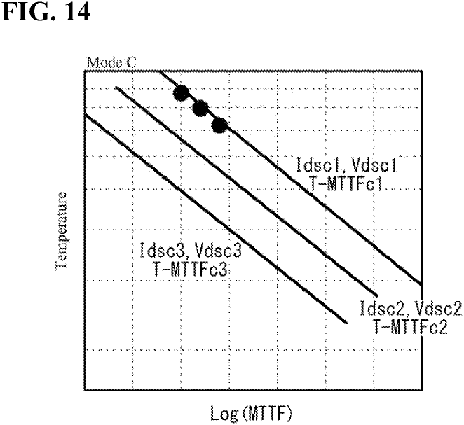

FIGS. 12 to 14 are Arrhenius plots illustrating temperature to the MTTF in modes A to C, respectively. The scale of the horizontal axis corresponds to the logarithm of the MTTF and the scale of the vertical axis corresponds to the reciprocal of temperature. Dots in FIGS. 12 to 14 indicate temperatures with respect to the MTTF obtained in FIGS. 9 to 11. The straight line is an approximate straight line of the dot. As shown in FIG. 12, for a plurality of drain currents and drain voltages (Idsa1, Vdsa1), (Idsa2, Vdsa2), and (Idsa3, Vdsa3) corresponding to first end portion E1, approximate straight lines T-MTTFa1, T-MTTFa2, and T-MTTFa3 are obtained. As shown in FIG. 13, for a plurality of drain currents and drain voltages (Idsb1, Vdsb1), (Idsb2, Vdsb2), and (Idsb3, Vdsb3) corresponding to second end portion E2, approximate straight lines T-MTTFb1, T-MTTFb2, and T-MTTFb3 are obtained. As shown in FIG. 14, for a plurality of drain currents and drain voltages (Idsc1, Vdsc1), (Idsc2, Vdsc2), and (Idsc3, Vdsc3) corresponding to direct component E3, approximate straight lines T-MTTFc1, T-MTTFc2, and T-MTTFc3 are obtained.

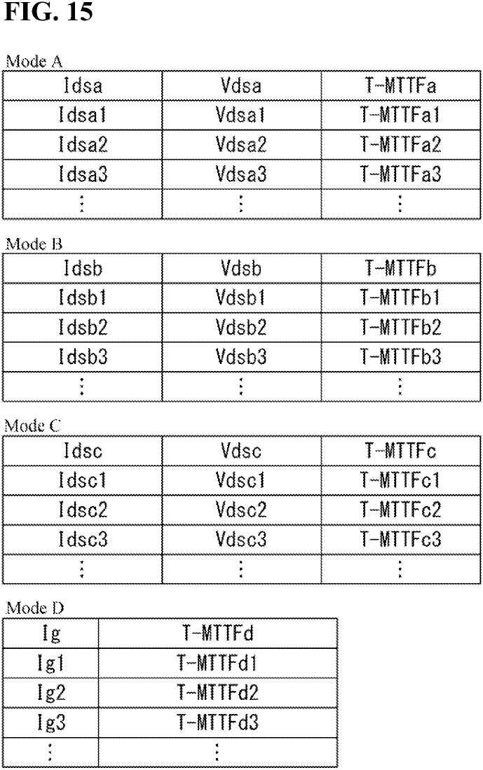

FIG. 15 is a diagram illustrating data stored in memory 24 of computer 20. As shown in FIG. 15, in mode A, T-MTTFa is stored in association with a drain current Idsa and a drain voltage Vdsa corresponding to first end portion E1. For example, T-MTTFa1, T-MTTFa2, and T-MTTFa3 are stored in association with (Idsa1, Vdsal), (Idsa2, Vdsa2), and (Idsa3, Vdsa3), respectively. The measured Ids and Vds are the current and voltage between source S and drain D in equivalent circuit 32. Thus, the measured Ids and Vds may be converted into a current and a voltage at the end of drain current source Id and the converted values may be stored in the memory. As T-MTTF, for example, a slope and an intercept of the approximate straight line of FIGS. 12 to 14 are stored. In mode B, T-MTTFb is stored in association with a drain current Idsb and a drain voltage Vdsb corresponding to second end portion E2. For example, T-MTTFb1, T-MTTFb2, and T-MTTFb3 are stored in association with (Idsb1, Vdsb1), (Idsb2, Vdsb2), and (Idsb3, Vdsb3), respectively. In mode C, T-MTTFc is stored in association with a drain current Idsc and a drain voltage Vdsc corresponding to direct component E3. For example, T-MTTFc1, T-MTTFc2, and T-MTTFc3 are stored in association with (Idsc1, Vdsc1), (Idsc2, Vdsc2), and (Idsc3, Vdsc3), respectively.

Furthermore, in an FET such as a GaN HEMT, a deterioration mode occurs due to a gate current. This deterioration mode is referred to as a mode D. The gate current is changed and MTTF is measured for each operating temperature in the same manner as in FIGS. 9 to 11. Similarly to FIGS. 12 to 14, T-MTTFd is measured for each gate current. Thus, in mode D, T-MTTFd is stored in association with a gate current Ig. For example, Ig1 to Ig3 are stored in association with T-MTTFd1 to T-MTTFd3, respectively.

### Example of Step S16 and S18

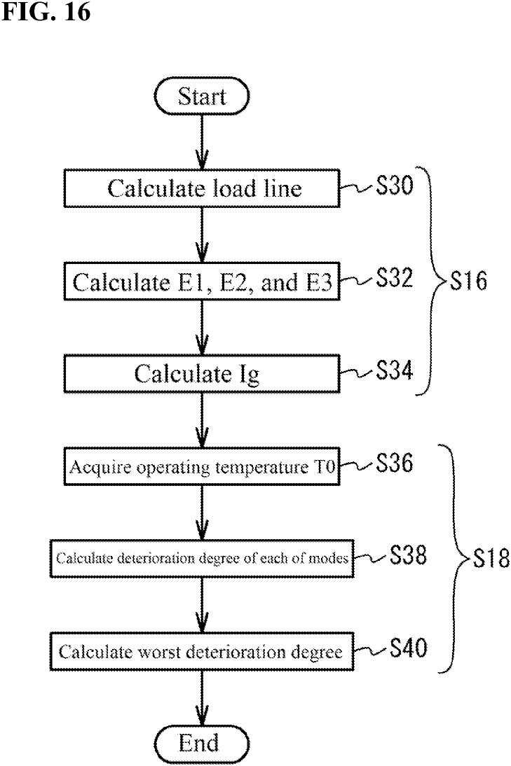

An example of steps S16 and S18 in FIG. 4 will be described. FIG. 16 is a flow chart illustrating an example of steps S16 and S18. As shown in FIG. 16, steps S30 to S34 correspond to step S16 of FIG. 4, and steps S36 to S40 correspond to step S18 of FIG. 4. Computer 20 uses the element values of matching circuits 12 and 14 set in step S10 using equivalent circuit 32 of FIG. 2 to calculate load line LC when input power Pin used in amplifier circuit 30 is input (step S30). Ammeter A1, voltmeters V1 and V2 in FIG. 2 are used to calculate load line LC. The current monitored by ammeter A1 is Ids, and the difference between the voltages monitored by voltmeters V2 and V1 is Vds.

Computer 20 calculates first end portion E1, second end portion E2, and direct component E3 of calculated load line LC (step S32). Computer 20 calculates gate current Ig (step S34). Gate current Ig is the sum of the currents monitored in ammeters A2 and A3. The gate current Ig is, for example, a maximum gate current or an average gate current when input power Pin is applied.

Computer 20 acquires an operating temperature T0 (step S36). An operating temperature T0 is the temperature at which the transistor operates. Operating temperature T0 may be input by the user in advance or may be calculated by computer 20. Computer 20 calculates the deterioration degree of each of modes A to D based on E1, E2, E3, Ig, and T0 (step S38). For example, when calculating the deterioration degree of mode A, computer 20 calculates T-MTTFa corresponding to E1 (Idsa, Vdsa) based on the table of mode A shown in FIG. 15. For example, when (Idsa, Vdsa) = (Idsa1, Vdsal), computer 20 calculates T-MTTFa1 as T-MTTFa. If E1 calculated in step S32 is not in mode A table of FIG. 15, interpolation may be used to calculate T-MTTFa. The inside of (Ids, Vds) plane is divided into a plurality of ranges in advance. Computer 20 may calculate T-MTTFa1 as T-MTTFa when (Idsa, Vdsa) is positioned within a predetermined range among the plurality of ranges, and may calculate T-MTTFa2 as T-MTTFa when (Idsa, Vdsa) is positioned within another predetermined range among the plurality of ranges. Computer 20 calculates MTTFa of mode A based on T-MTTFa and T0. T-MTTF is similarly calculated for modes B to D.

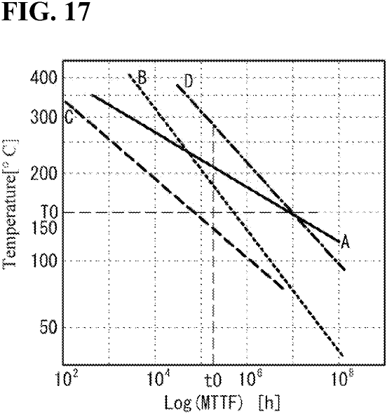

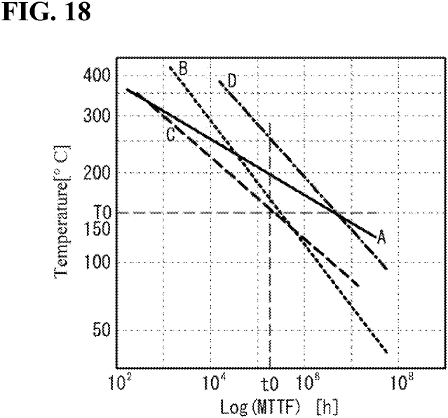

FIGS. 17 and 18 are Arrhenius plots illustrating temperature to MTTF in modes A-D. As shown in FIGS. 17 and 18, straight lines of temperature with respect to MTTF in modes A to D are illustrated. In step S38 of FIG. 16, computer 20 calculates the mode having the worst deterioration degree in operating temperature T0 among modes A to D (step S40). In FIGS. 17 and 18, the MTTF of mode C is the smallest at operating temperature T0. Therefore, computer 20 calculates the MTTF in the operating temperature T0 of mode C as the worst deterioration degree.

In step S20 of FIG. 4, it is determined whether the MTTF at operating temperature T0 of mode C satisfies a desired deterioration degree (e.g., t0). In FIG. 17, the MTTF at operating temperature T0 of mode C is less than t0. Therefore, computer 20 determines No in step S20. In FIG. 18, the MTTF at operating temperature T0 of mode C is greater than t0. Therefore, computer 20 determines Yes in step S20.

In the examples of FIGS. 15 to 18, the deterioration degree is calculated for modes A to D, but the number of modes may be one or more. T-MTTF is stored in association with Ids and Vds in E1 to E3, but there is a case where one of Ids and Vds does not affect deterioration. In this case, one of Ids and Vds that affects the deterioration may be associated with T-MTTF, and only one of Ids and Vds that affects the deterioration may be calculated in step S32. For example, only Ids may be calculated in mode B, and only Vds may be calculated in mode C.

Although the deterioration degree of mode D is calculated based on gate current Ig, there may be a case where at least one of the current value and the voltage value of diode Dg1 of equivalent circuit 32 affects the deterioration, and a case where at least one of the current value and the voltage value of diode Dg2 affects the deterioration. The deterioration degree of mode D may be calculated based on the value that affects the deterioration.

If operating temperature T0 is determined, step S36 may not be performed. In the table of FIG. 15, the MTTF may be stored instead of T-MTTF. Although the MTTF has been described as the deterioration degree, the deterioration degree may be other than the MTTF as long as it is an index indicating the deterioration degree of the electrical characteristic.

According to the first embodiment, computer 20 executes the program to calculate the radio frequency characteristic of amplifier circuit 30 based on the element value of matching circuit 14 and using equivalent circuit 32 of FET 10 (transistor) in amplifier circuit 30 as in step S12 of FIG. 4. As in step S16, if the calculated radio frequency characteristic of amplifier circuit 30 is a desired characteristic, at least one value of a current value and a voltage value at a predetermined portion within equivalent circuit 32 is calculated based on the element value of matching circuit 14 and using equivalent circuit 32. As in step S18, the deterioration degree of the electrical characteristic of FET 10 is calculated based on at least one value of the current value and the voltage value and using data in which at least one value of the current value and the voltage value and the deterioration degree of the electrical characteristic of FET 10 are associated with each other. Thus, since the deterioration degree of the electrical characteristic of FET 10 is calculated using the element value at which the desired radio frequency characteristic is obtained, it is possible to design amplifier circuit 30 in consideration of the deterioration degree.

Computer 20 further determines whether or not the calculated deterioration degree is a desired deterioration degree, as in step S20. If it is determined in step S20 that the calculated deterioration degree is not the desired deterioration degree, computer 20 changes the element value of matching circuit 14 in step S10, and then executes steps S12, S16, S18 and S20. As a result, computer 20 can design amplifier circuit 30 in consideration of the electrical characteristic.

In step S16, at least one value of a current value at an end of drain current source Id and a voltage value across both ends of drain current source Id within equivalent circuit 32 is calculated. Thus, as shown in FIG. 6, at least one value of the current value and the voltage value can be calculated without increasing the hysteresis due to the reactance component.

As in steps S30 and S32 of FIG. 16, at least two values of a first value, a second value, and a third value are calculated. The first value is at least one of a voltage value and a current value at first end portion E1 at which load line LC has a minimum voltage value in a current-voltage characteristic for a current value at an end of the current source and a voltage value across both ends of the current source within equivalent circuit 32. The second value is at least one of a voltage value and a current value at second end portion E2 at which load line LC has a maximum voltage value. The third value is at least one of a direct current component and a direct voltage component in load line LC. As in step S38, the deterioration degrees of at least two of modes A to C of FET 10 are calculated based on each of at least two values of E1 to E3, respectively. Accordingly, it is possible to calculate the deterioration degree of at least two of the different deterioration modes A to C in E1 to E3.

As shown in step S40 of FIG. 16, the worst deterioration degree among the deterioration degrees of the modes A to C is calculated as the deterioration degree of the electrical characteristic of FET 10. Thus, the deterioration degree of the electrical characteristic of FET 10 can be calculated from the plurality of modes.

In step S32, the first value, the second value, and the third value in E1, E2, and E3 are calculated, respectively. In step S38, the deterioration degrees of the three modes A to C in FET 10 are calculated based on the first value, the second value, and the third value, respectively. Accordingly, three deterioration degrees of different deterioration modes A to C in E1 to E3 can be calculated.

If the transistor is FET 10 with gate G connected to input terminal Tin and drain D connected to matching circuit 14, the current source in the equivalent circuit is drain current source Id. In FET 10, different deterioration modes A to C occur in first end portion E1, second end portion E2, and direct component E3 of load line FC. Therefore, when the transistor is FET 10, the deterioration degrees of modes A to C may be calculated based on E1 to E3. The transistor may be, for example, a bipolar transistor other than FET 10.

When FET 10 is a GaN HEMT, different deterioration modes A to C occur in E1, E2, and E3 of load line FC. When FET 10 is the GaN HEMT, the deterioration degrees of modes A to C may be calculated based on E1 to E3. The GaN HEMT is a HEMT using a GaN-based semiconductor. In the GaN HEMT, for example, a channel layer such as a GaN layer is stacked on a substrate such as a SiC substrate, and a barrier layer such as an AlGaN layer is stacked on the channel layer. A source electrode, a gate electrode, and a drain electrode are provided on the barrier layer.

In FET 10, there is a deterioration mode D due to the gate current and/or the gate voltage. Therefore, in step S34, a fourth value that is at least one of a current value and a voltage value is calculated. The current value is a current value at an end of at least one diode of a diode Dg2 between the gate and the source and diode Dg1 between the gate and the drain within equivalent circuit 32. The voltage value is a voltage value across both ends of at least one diode. In step S38, the deterioration degree of FET 10 in mode D is calculated according to the fourth value. Thus, the deterioration degree of deterioration mode D caused by the gate current and/or the gate voltage can be calculated.

In step S36, the operating temperature of FET 10 is obtained. In Step S38, the deterioration degree of FET 10 is calculated based on E1 to E3, Ig, and operating temperature T0 and using data in which E1 to E3, Ig, and T0 are associated with the deterioration degree. Thus, the deterioration degree at operating temperature T0 can be calculated.

It should be understood that the embodiments disclosed herein are illustrative in all respects and are not restrictive. The scope of the present disclosure is defined by the appended claims rather than by the foregoing description, and is intended to include all modifications within the meaning and scope equivalent to the appended claims.

What is claimed is:

1. A calculation device comprising:
a memory; and
a processor coupled to the memory, the processor being configured to:
in an amplifier circuit including an input terminal to which a radio frequency signal is input, a transistor configured to amplify the input radio frequency signal, an output terminal from which the amplified radio frequency signal is output, and a matching circuit connected between the transistor and the output terminal,
calculate, based on an element value of the matching circuit and using an equivalent circuit of the transistor, a radio frequency characteristic of the amplifier circuit;
if the calculated radio frequency characteristic of the amplifier circuit is a desired characteristic, calculate, based on the element value and using the equivalent circuit, at least one value of a current value and a voltage value at a predetermined portion within the equivalent circuit; and
calculate, based on the at least one value and using data in which the at least one value and a deterioration degree of an electric characteristic of the transistor are associated with each other, the deterioration degree of the electric characteristic of the transistor.

2. The calculation device according to claim 1, wherein
the processor determines whether the calculated deterioration degree is a desired deterioration degree, and
if it is determined that the calculated deterioration degree is not the desired deterioration degree, the processor changes the element value, calculates, based on the changed element value, the radio frequency characteristic, calculates the at least one value, calculates the deterioration degree, and determines whether the calculated deterioration degree is the desired deterioration degree.

3. The calculation device according to claim 1, wherein, in calculating of at least one value, the processor calculates at least one value of a current value at an end of a current source and a voltage value across both ends of the current source within the equivalent circuit as the at least one value.

4. The calculation device according to claim 1, wherein,
in calculating of at least one value, the processor calculates at least two values of a first value, a second value, and a third value, the first value being at least one of a voltage value and a current value at a first end portion at which a load line has a minimum voltage value in a current-voltage characteristic for a current value at an end of a current source and a voltage value across both ends of the current source within the equivalent circuit, the second value being at least one of a voltage value and a current value at a second end portion at which the load line has a maximum voltage value, the third value being at least one of a direct current component and a direct voltage component in the load line, and,
in calculating of the deterioration degree, the processor calculates, based on the at least two values, at least two deterioration degrees of the electric characteristic of the transistor, respectively.

5. The calculation device according to claim 4, wherein, in calculating of the deterioration degree, the processor calculates, as the deterioration degree of the electric characteristic of the transistor, a worst deterioration degree of the electric characteristic of the at least two deterioration degrees of the electric characteristic.

6. The calculation device according to claim 4, wherein,
in calculating of at least one value, the processor calculates the first value, the second value, and the third value, and,
in calculating of the deterioration degree, the processor calculates, based on the first value, the second value, and the third value, three deterioration degrees of the electric characteristic of the transistor, respectively.

7. The calculation device according to claim 4, wherein
the transistor is a field effect transistor (FET) having a gate connected to the input terminal and a drain connected to the matching circuit, and
the current source is a drain current source within the FET.

8. The calculation device according to claim 7, wherein,
in calculating of at least one value, the processor calculates a fourth value that is at least one of a current value and a voltage value, the current value being a current value at an end of at least one diode of a diode between the gate and a source and a diode between the gate and the drain within the equivalent circuit, the voltage value being a voltage value across both ends of the at least one diode, and,
in calculating of the deterioration degree, the processor calculates, based on the fourth value, a deterioration degree of an electric characteristic of the FET.

9. The calculation device according to claim 1, wherein
the calculation device acquires an operation temperature of the transistor, and,
in calculating of the deterioration degree of the electric characteristic of the transistor, the processor calculates, based on the at least one value and the operation temperature and using data in which the at least one value, the operation temperature, and the deterioration degree of the electric characteristic of the transistor are associated with each other, the deterioration degree of the electric characteristic of the transistor.

10. A calculation method to be executed by a computer, the method comprising:
in an amplifier circuit including an input terminal to which a radio frequency signal is input, a transistor configured to amplify the input radio frequency signal, an output terminal from which the amplified radio frequency signal is output, and a matching circuit connected between the transistor and the output terminal,
calculating, based on an element value of the matching circuit and using an equivalent circuit of the transistor, a radio frequency characteristic of the amplifier circuit;
if the calculated radio frequency characteristic of the amplifier circuit is a desired characteristic, calculating, based on the element value and using the equivalent circuit, at least one value of a current value and a voltage value at a predetermined portion within the equivalent circuit; and
calculating, based on the at least one value and using data in which the at least one value and a deterioration degree of an electric characteristic of the transistor are associated with each other, the deterioration degree of the electric characteristic of the transistor.

11. A non-transitory computer-readable recording medium storing a program that causes a computer to execute a process, the process comprising:
in an amplifier circuit including an input terminal to which a radio frequency signal is input, a transistor configured to amplify the input radio frequency signal, an output terminal from which the amplified radio frequency signal is output, and a matching circuit connected between the transistor and the output terminal,
calculating, based on an element value of the matching circuit and using an equivalent circuit of the transistor, a radio frequency characteristic of the amplifier circuit;
if the calculated radio frequency characteristic of the amplifier circuit is a desired characteristic, calculating, based on the element value and using the equivalent circuit, at least one value of a current value and a voltage value at a predetermined portion within the equivalent circuit; and
calculating, based on the at least one value and using data in which the at least one value and a deterioration degree of an electric characteristic of the transistor are associated with each other, the deterioration degree of the electric characteristic of the transistor.
